(19) United States
(12) Patent Application Publication
(10) Pub. No.: US 2022/0120800 A1
(43) Pub. Date: Apr. 21, 2022

(54) DEVICE FOR CHECKING LACK OF VOLTAGE IN AN ELECTRIC CIRCUIT

(71) Applicant: NEORATECH, Troyes (FR)

(72) Inventors: Thomas CAZOR, Rueil-Malmaison (FR); Mathias ARBET-PONT, Troyes (FR)

(21) Appl. No.: 17/428,261

(22) PCT Filed: Jan. 31, 2020
(86) PCT No.: PCT/FR2020/050155

§ 371 Date: Aug. 3, 2021

(30) Foreign Application Priority Data
Feb. 6, 2019 (FR) 1901198

(51) Int. Cl. G01R 29/12; G01R 19/155; G08B 21/18

(52) U.S. Cl. CPC G01R 29/12; G08B 21/182; G01R 19/155

(57) ABSTRACT

The device for checking lack of voltage in an electric circuit comprises a pair of flexible and insulating gloves (1a, 1b), a lack of voltage checking device (2) comprising at least one display screen (3) and two contact points (4), said device being noteworthy in that the lack of voltage checking device (2) is formed in a flexible electronic circuit comprising a flexible substrate and embedded in a first glove (1a) of the pair of flexible and insulating gloves (1a, 1a), said display screen (3) being flush on the surface of said glove (1a).

### TECHNICAL FIELD

The present invention relates to the field of safety devices during electrical installation inspections and more particularly to a device for checking the voltage of an electric circuit, which provides greater safety and saves time for the technicians carrying out these inspections.

### BACKGROUND

In the field of maintenance of electrical installations, it is well known that before carrying out any manipulation on electrical voltage lines, the technicians must first pass through four essential safety steps, namely identification, separation, condemnation and checking of lack of voltage, known as VAT. This step of checking lack of voltage (VAT) is carried out by means of an apparatus commonly known as DETEX (registered trademark) marketed by the CATU establishments, with the technicians also having to be equipped with all their safety equipment, namely a helmet, gloves and an insulating mat.

Thus, the technicians must first put on the gloves before handling the apparatus for checking lack of voltage (VAT) in order to check the lack of voltage. However, these gloves prevent easy handling, so that some technicians who do not put on the gloves before carrying out measurements with the apparatus for checking lack of voltage run the risk of being electrocuted during the VAT.

In order to remedy these disadvantages, devices have already been devised to provide better safety for the technicians.

This is, in particular, the case for the document CN104432685.

The document CN104432685 describes an insulating protective garment with a multimeter device. The insulating protective garment comprises an insulating protective garment body in the form of a jacket with glove ends, a liquid crystal display panel disposed on a glove of the insulating protective garment body, a positive probe and a negative probe disposed on the fingers of two gloves respectively, a multimeter module disposed on the chest of the insulating protective garment body and the liquid crystal display panel, the positive probe and the negative probe being connected to the multimeter module via wires.

However, this type of device has the disadvantage of being not very ergonomic, bulky, and expensive, and besides the fact, in case of high heat, it is uncomfortable for the technicians.

### SUMMARY OF THE INVENTION

One of the objectives of the invention is therefore to remedy at least one of these disadvantages by proposing a device for checking lack of voltage in an electric circuit which is simple and inexpensive in design, space-saving and ergonomic, and provides increased safety for technicians.

To this end and in accordance with the invention, there is proposed a device for checking lack of voltage in an electric circuit comprising a pair of flexible and insulating gloves, a lack of voltage checking device comprising at least one display screen and two contact points; said device being remarkable in that the lack of voltage checking device is formed in a flexible electronic circuit, comprising a flexible substrate, and embedded in a first glove of the pair of flexible and insulating gloves, said display screen being flush on the surface of said glove.

Preferably, the display screen of the lack of voltage checking device consists of a flexible LCD screen.

Each contact point comprises an insulating body, a conductive tip and a removable flexible cap adapted to protect said conductive tip.

In a first embodiment, the lack of voltage checking device comprises two female terminals moulded in the glove and adapted to receive the male terminals of the contact points.

In a second embodiment, the lack of voltage checking device comprises a reel for receiving the cables of the contact points.

According to another embodiment, the lack of voltage checking device comprises a transceiver adapted to communicate with a transceiver positioned in the insulating body of each contact point.

Preferably, said lack of voltage checking device is positioned on the top of the glove and is removable.

Furthermore, the second glove of the pair of gloves advantageously comprises at least one sensor adapted to detect the wearing of the glove by an operator.

Advantageously, the device comprises means for detecting an electrical potential at a predetermined distance.

Said detecting means comprise at least one sensor adapted to detect an electric potential field generated by an electric field, a control circuit adapted to analyse said electric potential and to compare it with a predetermined threshold value and to connect to signalling means.

Said sensor consists of a solenoid and the signalling means consist of sound and/or light signalling means.

### BRIEF DESCRIPTION OF THE FIGURES

Other advantages and characteristics will be better understood from the following description of several embodiments of the device for checking lack of voltage in an electric circuit according to the invention, given as non-limiting examples, from the attached drawings in which:

FIG. 1 is a perspective view of the device according to the invention carried by a technician,

FIG. 2 is a perspective view of the gloves of the device according to the invention,

FIG. 3 is a perspective view of a glove of the device according to the invention, in the rolled-up position, when not in use,

FIG. 4 is a perspective view of an embodiment of the device according to the invention worn by a technician.

### DETAILED DESCRIPTION

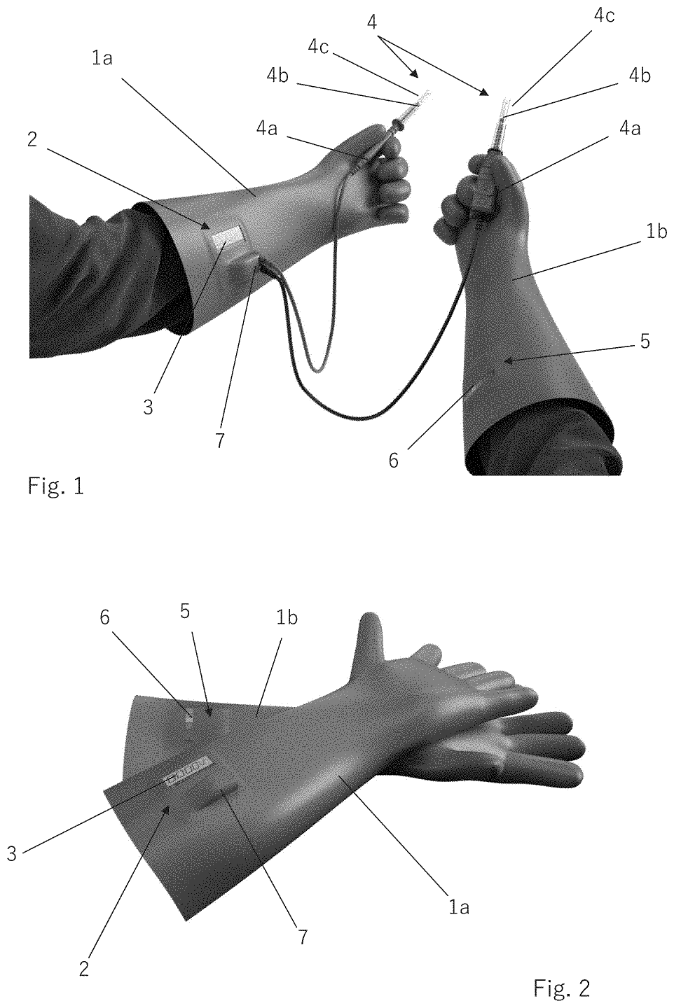

With reference to FIGS. 1 and 2, the device for checking lack of voltage in an electric circuit according to the invention comprises a pair of flexible and electrically insulating gloves 1a, 1b, a lack of voltage checking device 2 comprising at least one display screen 3 and two contact points 4, preferably contact points 4 of protection index IP2X well known to the person skilled in the art. The gloves 1a, 1b consist of gloves well known to the person skilled in the art and comply, in particular, with the requirements of standards IEC 60903 and NF EN 60903. They are usually obtained in latex, offering high dielectric characteristics, and may possibly consist of so-called composite gloves which offer superior mechanical protection against perforations and tears. In a particularly advantageous manner, the lack of voltage checking device 2 is formed in a flexible electronic circuit, not shown in the figures, comprising a flexible substrate, and embedded in a first glove 1a of the pair of flexible and insulating gloves 1a, 1b, and said display screen 3 being flush on the surface of said glove 1a. Said lack of voltage checking device 2 comprises phase and neutral locating means, continuity testing means and a phase rotation controller, said lack of voltage checking device 2 having an IP65 protection rating.

For example, the flexible electronic circuit comprises a first flexible substrate comprising a first series of electrical contacts, delimiting on the one hand a first contact surface, and on the other hand a first substrate surface, devoid of electrical contacts, a second flexible substrate comprising a second series of contacts, delimiting on the one hand a second contact surface, and on the other hand a second substrate surface, devoid of electrical contacts, said electrical contactor further comprising at least one spacer disposed between said first and second substrate surfaces. Said circuit is obtained by carrying out a step of depositing at least a first layer of polymerisable varnish on said first substrate surface by screen printing, of affixing said second substrate surface to the previously screen printed varnish layer, in relation to said first substrate surface, so that the varnish forms said spacer, and polymerisation of the previously screen-printed layer of polymerisable varnish, on which the second substrate surface is affixed, as described in the French patent application FR 3 027 153, for example.

It goes without saying that the flexible electronic circuit may be obtained by any other method well known to the person skilled in the art without going beyond the scope of the invention.

Furthermore, the display screen 3 of the lack of voltage checking device 2 preferably consists of a flexible LCD screen. It is obvious that the flexible LCD screen may be substituted by any other flexible or non-flexible display screen well known to the person skilled in the art without going beyond the scope of the invention.

Each contact point 4 comprises an insulating body 4a, a conductive tip 4b and a removable flexible cap 4c adapted to protect said conductive tip 4b.

Furthermore, the second glove 1b of the pair of gloves 1a, 1b advantageously comprises at least one sensor adapted to detect the wearing of the glove by an operator, said sensor not being shown in the figures.

In addition, and advantageously, the device comprises means 5 for detecting an electrical potential at a predetermined distance. Said detecting means 5 comprise at least one sensor, not shown in the figures, adapted to detect an electric potential field generated by an electric field, and a control circuit adapted to analyse said electric potential and comparing it with a predetermined threshold value, said control circuit being connected to the signalling means 6. Said sensor consists of a solenoid and the signalling means consist of sound and/or light signalling means.

It goes without saying that the sensor may consist of any other equivalent sensor well known to the person skilled in the art without going beyond the scope of the invention.

Thus, when an electric potential field is detected by the sensor, the control circuit generates an intermittent and audible alarm signal, which has a repetition rate varying in proportion to the strength of the field, and a visible alarm signal. It should be noted that the detecting means 5 does not have an on-off button, the detecting means being disabled by being disposed in a shielded carrying case. As an accessory, the device indicates the presence of current by a permanent red light signal and an audible signal above 80 dB(A).

In this embodiment, the lack of voltage checking device 2 is positioned in a housing on the inner side of the glove 1a, close to the proximal end of said glove 1a. Furthermore, said lack of voltage checking device 2 is advantageously removable so that, when the gloves 1a, 1b are worn, the latter is removed and positioned in the housing of a new glove 1a, which allows to reduce the cost of the device according to the invention. In addition, the lack of voltage checking device 2 comprises two female terminals 7 moulded into the glove 1a and adapted to receive the male terminals of the contact points 4.

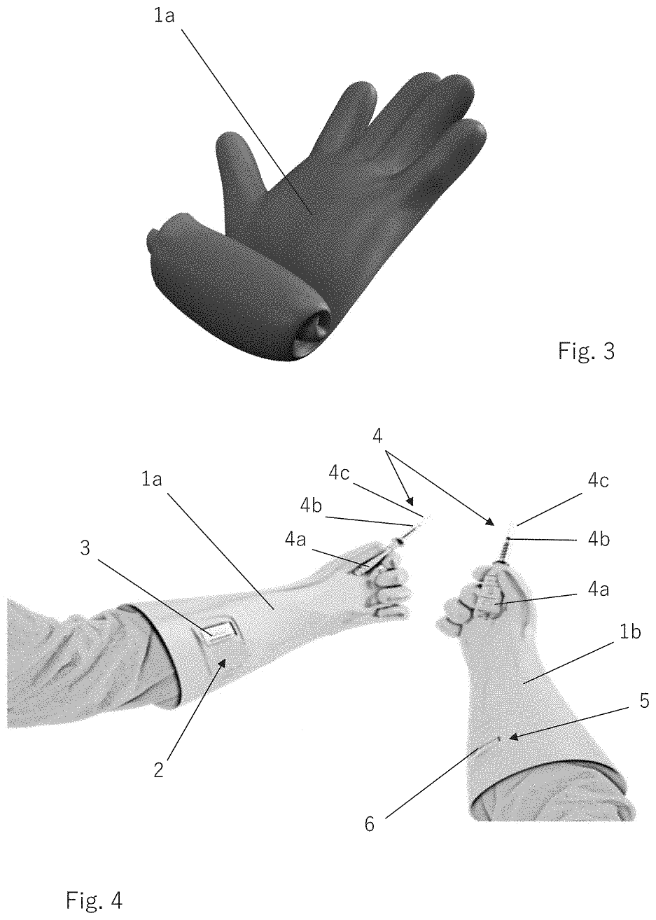

It will be observed, with reference to FIG. 3, that the gloves 1a, 1b can be easily rolled up for storage due to the flexibility of the lack of voltage checking device 2, without having to remove said lack of voltage checking device 2 from its housing.

According to an alternative embodiment of the device according to the invention, not shown in the figures, the lack of voltage checking device may comprise a reel for receiving the cables of the contact points 4.

According to another embodiment of the device according to the invention, with reference to FIG. 4, the device for checking lack of voltage of an electric circuit according to the invention comprises in the same way as before a pair of flexible and electrically insulating gloves 1a, 1b, a lack of voltage checking device 2 comprising at least one display screen 3 and two contact points 4. Said lack of voltage checking device 2 is formed in a flexible electronic circuit, not shown in the figures, comprising a flexible substrate, and embedded in a first glove 1a of the pair of flexible and insulating gloves 1a, 1b, and said display screen 3 being flush on the surface of said glove 1a. Furthermore, the display screen 3 of the lack of voltage checking device 2 preferably consists of a flexible LCD screen. It is obvious that the flexible LCD screen may be substituted by any other flexible or non-flexible display screen well known to the person skilled in the art without going beyond the scope of the invention.

Each contact point 4 comprises an insulating body 4a, a conductive tip 4b and a removable flexible cap 4c adapted to protect said conductive tip 4b.

Furthermore, the second glove 1b of the pair of gloves 1a, 1b advantageously comprises at least one sensor adapted to detect the wearing of the glove by an operator, said sensor not being shown in the figures.

In addition, and advantageously, the device comprises means 5 for detecting an electrical potential at a predetermined distance. Said detecting means 5 comprise at least one sensor, not shown in the figures, adapted to detect an electric potential field generated by an electric field, and a control circuit adapted to analyse said electric potential and comparing it with a predetermined threshold value, said control circuit being connected to the signalling means 6. Said sensor consists of a solenoid and the signalling means consist of sound and/or light signalling means.

The device differs from the one described above in that the lack of voltage checking device comprises a transceiver, not shown in the figures, adapted to communicate with a transceiver, not shown in the figures, positioned in the insulating body of each contact point 4.

Finally, it is well understood that the present invention is in no way limited to the embodiments described above and that many modifications may be made thereto without departing from the scope of the appended claims.

1. A device for checking lack of voltage in an electric circuit, comprising a pair of flexible and insulating gloves, a lack of voltage checking device comprising at least one display screen and two contact points,
characterized in that the lack of voltage checking device is formed in a flexible electronic circuit, comprising a flexible substrate, and embedded in a first glove of the pair of flexible and insulating gloves, said display screen being flush on the surface of said glove.

2. The device according to claim 1,
characterized in that the display screen of the lack of voltage checking device consists of a flexible LCD screen.

3. The device according to claim 1,
characterised in that each contact point comprises an insulating body, a conductive tip and a removable flexible cap adapted to protect said conductive tip.

4. The device according to claim 1,
characterised in that the lack of voltage checking device comprises two female terminals moulded in the glove and adapted to receive the male terminals of the contact points.

5. The device according to claim 1,
characterised in that the lack of voltage checking device comprises a reel for receiving the cables of the contact points.

6. The device according to claim 1,
characterised in that the lack of voltage checking device comprises a transceiver adapted to communicate with a transceiver positioned in the insulating body of each contact point.

7. The device according to claim 1,
characterised in that the second glove of the pair of gloves comprises at least one sensor adapted to detect the wearing of the glove by an operator.

8. The device according to claim 1,
characterised in that the lack of voltage checking device is positioned on top of the glove.

9. The device according to claim 1,
characterised in that it comprises means for detecting an electrical potential at a predetermined distance.

10. The device according to claim 9,
characterized in that said detecting means comprise at least a sensor adapted to detect an electric potential field generated by an electric field, a control circuit adapted to analyse said electric potential and to compare it with a predetermined threshold value and to connect to signalling means.

11. The device according to claim 10,
characterised in that the sensor consists of a solenoid.

12. The device according to claim 10,
characterised in that the signalling means consist of sound and/or light signalling means.

13. The device according to claim 1,
characterised in that the lack of voltage checking device is removable.
